(19) United States
(12) Patent Application Publication
(10) Pub. No.: US 2009/0242131 A1
(43) Pub. Date: Oct. 1, 2009

(54) ECR PLASMA SOURCE

(75) Inventors: Joachim Mai, Nobitz (DE); Valerl Fell, Glauchau (DE); Bernd Rau, Chemnitz (DE)

Correspondence Address: JORDAN AND HAMBURG LLP, 122 EAST 42ND STREET, SUITE 4000, NEW YORK, NY, 10168, US

(73) Assignee: Roth & Rau AG, Hohenstein-Ernstthal (DE)

(21) Appl. No.: 12/310,081

(22) PCT Filed: Aug. 8, 2007
(86) PCT No.: PCT/DE2007/001441

§ 371 Date: Mar. 25, 2009

(30) Foreign Application Priority Data
Aug. 9, 2006 (DE) 10 2006 037 144.5

(51) Int. Cl. C23F 1/00; B01J 19/12; C23C 16/00; H05H 1/46

(52) U.S. Cl. 156/345.42; 422/186.03; 118/723 MA; 204/298.37

(57) ABSTRACT

The invention relates to an ECR plasma source comprising a coaxial microwave supply line with an internal conductor and an external conductor, wherein the internal conductor with one end as the antenna passes through a vacuum flange in insulated fashion, which vacuum flange closes off an opening in the wall to the plasma space. A multipole magnet arrangement is provided coaxially with respect to the microwave supply line and its magnetic fields pass through the vacuum flange and form an annular-gap magnetic field in the plasma space coaxially with respect to the antenna. The antenna protrudes directly into the plasma space and, in comparison with the internal conductor, it has a radially larger antenna head at which an underside is provided parallel to the vacuum flange in such a way that an annular gap is formed between the vacuum flange and the underside and that the plasma space is delimited coaxially with respect to the antenna and radially outside the annular-gap magnetic field by means of a shield, whose end side facing away from the vacuum flange defines the plasma outlet opening.

### BACKGROUND OF THE INVENTION

The invention relates to an ECR plasma source as claimed in the precharacterizing clause of claim 1, in particular for treatment of surfaces in the low-pressure range, for example for surface activation, for cleaning, for removing matter from or for coating of substrates. The ECR plasma source comprises a coaxial microwave supply having an inner conductor and an outer conductor, which pass in an insulated manner through a vacuum flange which closes an opening in the wall to the plasma space. The ECR plasma source furthermore comprises an antenna which, as one end of the inner conductor, passes through the vacuum flange in an insulated manner, and a multipole magnet arrangement which is arranged coaxially with respect to the microwave supply and whose magnetic fields pass through the vacuum flange and form an annular magnetic field around the antenna in the plasma area.

According to the prior art, a wide range of ECR plasma sources as well as plasma and ion-beam methods are known. For example, EP 0 448 077 B1 discloses a microwave plasmatron for production of a microwave discharge which is supported by a magnetic field, comprising a discharge space, an injection arrangement for the microwaves into the discharge space, and magnets. One or more hollow-cylindrical magnets is or are arranged on a surface waveguide and is or are surrounded by a U-shaped casing composed of ferromagnetic material in such a way that the open face rests on the surface waveguide and the injection arrangement for the microwaves is fitted centrally with respect to the hollow-cylindrical magnet. The vacuum oscillation of the discharge area from the injection point for the microwaves is ensured by a quartz-glass cup through which microwaves can pass. The hollow-cylindrical magnets may be coils or permanent magnets.

The electron cyclotron effect, referred to for short as the ECR effect, is used by the combination of the discharge with magnetic fields. This makes it possible, in particular, to extend the operating pressure range to very much lower pressures, down to about 10⁻⁵ mbar.

By way of example, the microwave plasmatron is operated in a pressure range of 10⁻² Pa with a microwave power of 400 W, and reliably initiates a plasma. Irrespective of the nature of the gas, ion densities of between 3 to 10×10¹⁰ cm⁻³ are achieved. Ion currents with homogeneous current density distributions up to 3 mA/cm² over a diameter of 6 inches are extracted from the plasma.

One particular disadvantage in the practical use of such plasma sources is that considerable maintenance measures are required for the discharge area. For example, frequent cleaning of the coating system is necessary, thus considerably increasing the costs of the coating process.

Particularly in the case of plasma coating processes, layers which are poorly electrically conductive to highly conductive are created, depending on the layer materials that are used. In this case, the growing layers cover not only the sample bodies used, but to a greater or lesser extent also all those surfaces of components throughout the entire coating system which are located in the immediate vicinity. This can lead to a time-dependent influence on the coating result, and restricts the possible coating times.

One frequent cause for the restriction of the coating time is conductive layers which produce short circuits in voltage or current conduction and prevent the further injection of electrical power at the coupling windows of electrodeless plasma sources.

### SUMMARY OF THE INVENTION

The invention is therefore based on the object of providing an ECR plasma source which, in a simple manner, overcomes the disadvantages of the prior art and allows the ECR plasma source to be operated for long periods without disturbances.

An ECR plasma source according to the prior art, comprising a coaxial microwave supply having an inner conductor and an outer conductor, wherein one end, as an antenna, of the inner conductor passes in an insulated manner through a vacuum flange which closes an opening in the wall to the plasma space and having a multipole magnet arrangement which is arranged coaxially with respect to the microwave supply and whose magnetic fields pass through the vacuum flange and form an annular gap magnetic field around the antenna in the plasma area, is advantageously developed further.

According to the invention, the antenna projects directly into the plasma space. There is accordingly no quartz-glass cup or ceramic cup, which is provided according to the prior art and sheaths the antenna.

For the purposes of the invention, the plasma space is bounded coaxially with respect to the antenna and with respect to the annular gap magnetic field by a shield which is held on the vacuum flange. The end face of the shield, facing away from the vacuum flange, forms the plasma outlet opening to the vacuum chamber or plasma treatment chamber.

Furthermore, the antenna has an antenna head which is radially larger than the inner conductor and has an underside parallel to the vacuum flange, such that an annular gap is formed between the vacuum flange and the underside.

The height and the radial length of the annular gap as well as the geometric arrangement of the shield are set such that the radially inner surface of the annular gap is located in the optical shadow area with respect to the vacuum chamber or plasma treatment chamber.

The radial length of the annular gap is advantageously greater than lambda/4 of the exciter frequency. The height of the annular gap is set in accordance with the known rules for the dimensions of dark space shielding such that a plasma shadow area is formed in the annular gap and plasma initiation is reliably precluded.

The coupling surface of the antenna which is located opposite the underside of the antenna head is advantageously at least partially in the form of a cone, a truncated cone or a sphere segment. This surface configuration results in advantageous emission of the microwave power in the direction of the annular magnetic field of the multipole magnet arrangement, thus ensuring reliable initiation and maintenance of an ECR plasma in the area of the annular magnetic field. In this case, the arrangement of the shield also advantageously acts coaxially with respect to the annular gap magnetic field in order to bound the plasma space.

The carrier gas and reactive gases can be supplied to the vacuum chamber in a known manner. In this case, a supply, for example for the carrier gas, can also be provided via an axial bore in the inner conductor. The outlet opening of the gas supply can in this case be located directly in the area of the emission of the microwave power from the antenna.

The ECR plasma sources according to the invention can also be arranged parallel, in the form of rows and columns as an array, using a multiplicity of individual ECR plasma sources, for plasma treatment of relatively large areas.

The invention will be explained in more detail in the following text using two exemplary embodiments.

### BRIEF DESCRIPTION OF THE DRAWINGS

FIG. 1 is a section through an ECR plasma source according to a first embodiment of the invention.

FIG. 2 is a perspective overall illustration of the ECR plasma source shown in FIG. 1.

FIG. 3 shows an ECR plasma source according to a second embodiment of the invention, modified in comparison to FIG. 1, in a plasma coating device.

### DETAILED DESCRIPTION OF THE INVENTION

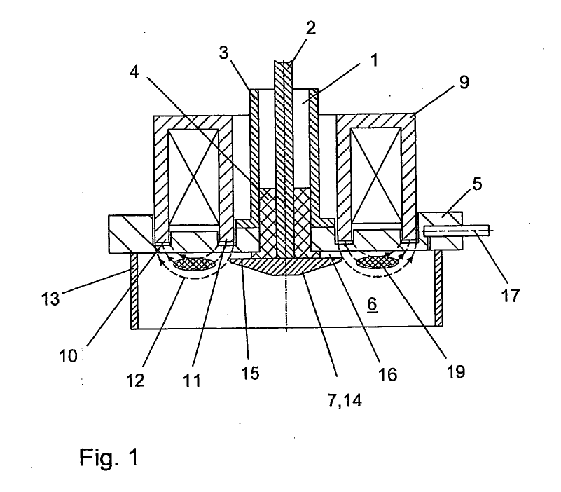

FIG. 1 shows the basic design of an ECR plasma source according to the invention. The ECR plasma source comprises a coaxial microwave supply 1 having an inner conductor 2 and an outer conductor 3 which is coaxial with respect to the inner conductor 2. The inner conductor 2 is insulated from the outer conductor 3 by a dielectric body 4. In this case, the dielectric body 4 at the same time ensures that the inner conductor 2 passes through a vacuum flange 5 in an insulated manner, such that the corresponding end of the inner conductor 2 projects freely into the plasma area.

The vacuum flange 5 is in the form of a mounting flange which closes an opening in the wall to the plasma space 6 in a vacuum tight manner.

That end of the inner conductor 2 which passes through the vacuum flange 5 and projects into the plasma space 6 forms the antenna 7 of the microwave supply 1. A multipole magnet arrangement 8 having an iron casing 9 and fitted with permanent magnets is arranged coaxially with respect to the microwave supply 1 outside the plasma space 6. An annular gap magnetic field 12 is produced coaxially around the antenna 7 in the area of pole pieces 10 and 11 of the iron casing 9, passes through the vacuum flange 5 and extends into the plasma space 6.

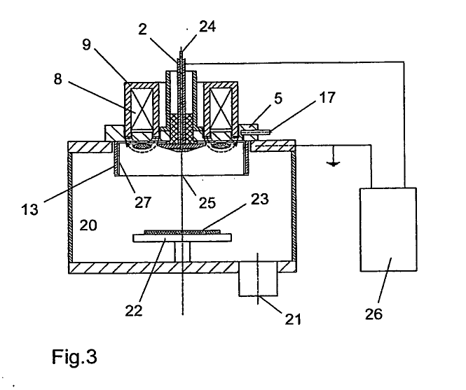

A shield 13 is arranged coaxially with respect to the antenna 7 and radially outside the annular gap magnetic field 12, and its end surface facing away from the vacuum flange forms the plasma outlet opening 25 (FIG. 3). The shield 13 bounds the plasma space 6 and advantageously influences the formation of an ECR plasma in the plasma space 6.

According to the invention, the antenna 7 is in the form of an antenna head 14 which is radially larger than the inner conductor 2 and has an underside 15 parallel to the vacuum flange 5 such that an annular gap 16 is formed between the vacuum flange 5 and the underside 15 of the antenna head 14. Opposite its underside 15, the antenna head 14 is in the form of a truncated cone. This results in microwave power advantageously being emitted in the direction of the annular gap magnetic field 12.

In the exemplary embodiment I, a carrier gas or reactive gas is supplied via a bore 17 in the vacuum flange 5.

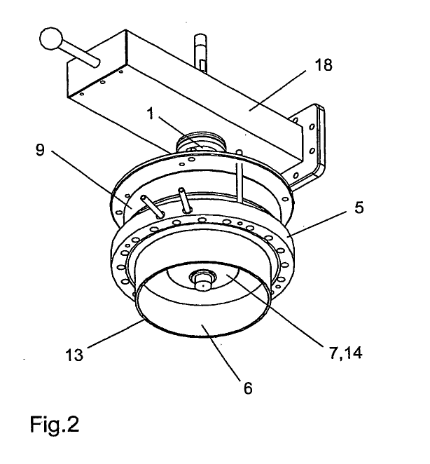

In order to assist understanding, FIG. 2 also shows a perspective illustration of the ECR plasma source according to exemplary embodiment I. In addition to FIG. 1, this also shows a microwave applicator 18, which is used as a wave transformer between the rectangular waveguide and the microwave supply 1 and for approximate microwave matching to a microwave generator, which is not illustrated here.

### Exemplary Embodiment II

With regard to exemplary embodiment II, FIG. 3 shows a similar embodiment of the ECR plasma source to that shown in FIG. 1, but schematically in conjunction with a coating device, essentially comprising a vacuum chamber 20 having a pump connecting stub 21 and a substrate mount 22 on which substrates 23 to be treated can be positioned.

The ECR plasma source according to the invention is arranged with the plasma outlet opening 25, which corresponds to the end face of the shield 13 facing away from the vacuum flange 5, parallel to the substrate mount 22.

In addition to the bore 17 corresponding to exemplary embodiment I, a bore 24 is provided centrally in the inner conductor 2. Carrier gas and reactive gases can be supplied selectively into the vacuum chamber 20 via the two bores 17 and 24.

As in the exemplary embodiment I, the inner conductor 2 and the antenna 7 are arranged in an insulated manner in the outer conductor 3 of the microwave supply 1. An additional voltage supply 26 can therefore be connected to the inner conductor 2 with the antenna 7. In the exemplary embodiment II, the shield 13 is also provided with insulating cladding 27 internally. The ECR plasma can thus be set to potentials of different magnitude with respect to ground potential.

Both DC voltage sources and AC voltage sources can alternatively be used for the voltage supply. For example, if a more positive potential with respect to ground potential is set on the microwave supply 1, then ions are extracted in the direction of the substrates 23 which, for example, are at ground potential. If an AC voltage is connected, then this leads to superimposition with the ECR plasma, thus resulting in an alternating edge-layer potential being formed. Ions or electrons of different density are extracted depending on the instantaneous polarity and magnitude of the edge-layer potential of the ECR plasma with respect to the substrate potential. The ECR plasma source then becomes a plasma-beam source.

The specific ECR plasma source according to the invention may, for example, have the following design dimensions. In this case, the dimensions of the vacuum flange 5 correspond to the ISO Standard 3669 for DN 160 CF. The plasma space 6 is governed by the pot-shaped shield 13 with a height of 45 mm and a diameter of 145 mm. The internal, insulating cladding 27 has corresponding dimensions. The cladding may also optionally be replaceable and may be composed of other materials, for example aluminum foil.

The antenna head 14, which is in the form of a truncated cone, has a height of 25 mm and a diameter on the lower face of 15 to 80 mm, and is manufactured from stainless steel.

The annular gap 16 between the vacuum flange 5 and the lower face 15 has a height of 4 mm and a radial length of 30 mm. This does not allow any plasma to be initiated in the annular gap 16 in the typical operating range of an ECR plasma source with a pressure of 1×10⁻⁴ to 1×10⁻² mbar.

Interacting with the shield 13, the radially inner surface of the annular gap 16 is thus advantageously located in the optical shadow space with respect to the vacuum chamber or plasma treatment chamber. In addition, the radially inner surface of the annular gap 16 is located in the plasma shadow space, as a result of which the annular gap 16 can also not be coated by particles moving in the plasma.

The ECR plasma source will be described in more detail in the following text in use for plasma-assisted layer deposition.

Once the required atmosphere has been set in the vacuum chamber 20 having the plasma space 6, the microwave power is supplied via the microwave applicator 18 to the microwave supply 1 and is emitted from the antenna head 14 of the antenna 7 into the plasma space 6. The particular shape of the antenna head 14 with respect to the shield 13 results in the microwave power being superimposed on the annular gap magnetic field 14, and an electron cyclotron effect occurs in the plasma space 6, that is to say an ECR plasma 19 is initiated and maintained in this space.

The embodiment of the antenna head 14 of the antenna 7 according to the invention surprisingly allows the emission of the microwave power without undesirable plasma initiation taking place adjacent to the antenna 7, which could lead to restriction of the emitter characteristics of the antenna. This is achieved essentially by the particular shape of the antenna head 14 and the geometric arrangement of the shield 13 to bound the plasma area 6 with respect to the location of the annular gap magnetic field 12, where the ECR plasma 19 is formed.

The simple embodiment of the annular gap 16 between the underside 15 of the antenna head 14 and the vacuum flange 5 is particularly advantageous. In the exemplary embodiment, the annular gap 16 is formed in a simple manner by the antenna head 14 being in the shape of a truncated cone. The particular shape of the antenna head 14 also satisfies all the preconditions for an advantageous microwave emitter.

The emitter characteristics of the antenna 7 and the radial length of the annular gap 16 can be varied in a simple manner by varying the height and the diameter of the truncated cone. If the gap length is set to be at least lambda/4 (wavelength/4) of the exciter frequency, then this also has an advantageous effect on the emitter characteristics of the antenna 7. This prevents undesirable plasma initiation directly adjacent to the antenna, resulting in a short-circuiting of the discharge.

It is particularly important in this case that the radially inner surface of the annular gap 16 is not coated during the deposition of conductive and insulating layers, thus avoiding the maintenance tasks which are required at short time intervals in solutions according to the prior art.

The form of the ECR plasma 4 that is produced can easily be adapted or influenced empirically by the height of the shield 13 and by the distance between the shield 13 and the antenna 7.

In one specific application, the ECR plasma source was used for deposition of hard amorphous carbon layers. In this case, an atmosphere with acetylene was used as the reactive gas and carbon carrier in the coating chamber. The process pressure was about 5×10⁻⁴ mbar. With the substrates 23 being at a distance of about 100 mm from the plasma outlet opening 25 on the shield 13 of the ECR plasma source, it was possible to achieve a mean coating rate of about 20 nm/min to about 40 nm/min, depending on the microwave power used.

During a coating test with a coating duration of more than 40 h, using the process parameters mentioned above, no changes could be observed in the microwave matching or in the stability of the ECR plasma. The layer thickness of the deposited carbon layer was in this case about 100 μm. These results indicate that the ECR plasma source according to the invention is particularly suitable for deposition of conductive thin layers.

1-7. (canceled)

8. An ECR plasma source for providing plasma to a plasma space, comprising a vacuum flange forming a wall of the plasma space, a coaxial microwave supply comprising an inner conductor and an outer conductor, the inner conductor being electronically insulated from the vacuum flange, an end of the inner conductor extending through the vacuum flange and comprising an antenna including an antenna head in and directly exposed to the plasma space, an annular shield arranged coaxially with respect to the coaxial microwave supply and being connected to the vacuum flange and a distal peripheral edge of the shield defining an outlet opening for the plasma, a multiple magnet array arranged coaxially with respect to the coaxial microwave supply and so situated that magnetic fields thereof pass through the vacuum flange and form an annular gap magnetic field in the plasma space coaxially with respect to the antenna, radially larger than the head of the antenna and radially smaller than the shield, the antenna head being coaxial with and radially larger than the inner conductor and having an underside parallel to and spaced from the vacuum flange whereby an annular gap is formed between the vacuum flange and the underside of the antenna head.

9. An ECR plasma source according to claim 8, wherein a radially inner surface of the annular gap formed between the underside of the antenna head and the vacuum flange is located in an optical shadow between the plasma outlet opening and an outer edge of the underside of the antenna head.

10. An ECR plasma source according to claim 8, wherein the radial length of the annular gap formed between the underside of the antenna head and the vacuum flange is greater than one-quarter wavelength of a predetermined exciter frequency for the plasma source and height of said annular gap is predetermined so that a plasma shadow is formed in the annular gap thereby to preclude plasma initiation within the plasma shadow.

11. An ECR plasma source, wherein the antenna head has a distal surface comprising a coupling surface for coupling with a process gas in the plasma space to form the plasma and at least a portion of the coupling surface comprises non-planar surfaces of a cone, truncated cone or sphere segment.

12. An ECR plasma source according to claim 8, further comprising an axial bore in the inner conductor for supplying process gas to the plasma space.

13. An ECR plasma source, further comprising a voltage source connected to the inner conductor, and an insulating cladding on the shield.

14. An array of ECR plasma sources according to claim 8 in the form of parallel columns and rows for treatment of a large area.
